(19) United States
(12) Patent Application Publication
(10) Pub. No.: US 2025/0390412 A1
(43) Pub. Date: Dec. 25, 2025

(54) METHOD OF ANALYZING A MEASUREMENT SIGNAL

(71) Applicant: Rohde & Schwarz GmbH & Co. KG, Muenchen (DE)

(72) Inventors: Andrew SCHAEFER, Muenchen (DE); Wolfgang HERBORDT, Muenchen (DE)

(21) Appl. No.: 18/748,707

(22) Filed: Jun. 20, 2024

(51) Int. Cl. G06F 11/34

(52) U.S. Cl. CPC G06F 11/3452

(57) ABSTRACT

A method of analyzing a measurement signal is described. The method includes receiving a measurement signal, wherein the measurement signal is a digitized signal; and applying a model to the measurement signal, thereby creating an embedding of signal segments of the measurement signal in a manifold where signal segments having a higher degree of similarity between each other are positioned closer to one another in the manifold and signal segments having a lower degree of similarity between each other are positioned more distant to one another in the manifold.

### FIELD OF THE DISCLOSURE

The present disclosure relates to a method of analyzing a measurement signal, for example wherein a model is applied to the measurement signal. In addition, embodiments of the present disclosure relate to a test and/or measurement instrument.

### BACKGROUND

In the state of the art, methods exist that can detect anomalies within measurement signals. For example, techniques like triggering or mask testing can be used. However, existing approaches typically require a manual setup of the conditions for detecting the anomalies. In particular, prior knowledge about characteristics of potential anomalies is necessary. Moreover, it is usually required to adjust many parameters for defining the detection conditions. This can make it difficult for a user to search for anomalies efficiently.

Accordingly, there is a need for a method of analyzing a measurement signal capable of detecting anomalies that can be set up and adapted in a time-efficient and user-friendly way.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

The present disclosure provides a method of analyzing a measurement signal. In an embodiment, the method comprises: receiving a measurement signal, wherein the measurement signal is a digitized signal; and applying a model to the measurement signal, thereby creating an embedding of signal segments of the measurement signal in a manifold where signal segments having a higher degree of similarity between each other are positioned closer to one another in the manifold and signal segments having a lower degree of similarity between each other are positioned more distant to one another in the manifold.

Accordingly, the measurement signal can be analyzed without having to perform a complex preliminary setup of analysis parameters. Instead, a mostly or fully automatic signal analysis can be provided by applying the model to the measurement signal.

In an embodiment, the signal segments may be classified as either normal segments or as outlier segments, according to their position within the manifold. Hence, a particularly user-friendly and time-efficient outlier detection can be enabled.

In an embodiment, the normal segments and the outlier segments are spaced from each other within the manifold. The detection of outlier segments within the measurement signal can thus be performed with a high degree of reliability.

In an embodiment, the frequency or a count of normal segments and outlier segments may be output as data. Hence, key information for evaluating the measurement signal can be provided in concise form. Additionally or alternatively, the frequency or the count of normal segments and outlier segments may be visualized in a generated diagram. A user can thus be provided with an illustrative overview about characteristics of the measurement signal.

According to one aspect, the model, for example, may be applied to the measurement signal by an electronic circuit in real time. Real-time signal analysis and in particular real-time outlier detection can thus be enabled. In an embodiment, the electronic circuit comprises at least one of an application-specific integrated circuit, a field-programmable gate array, a graphics processing unit, a central processing unit, or other processor-like circuit.

In an embodiment, a metric may be used to determine a frequency or a count of the normal segments and the outlier segments. Thus, particularly accurate results can be achieved, since a metric (metric tensor) allows defining a distance in the manifold in a precise and consistent way. In an embodiment, the metric is used for determining distances between the signal segments. Optionally, angles may also be defined for the manifold via the metric.

For example, the metric may be determined via a machine learning model. Hence, the metric can be determined in a mostly or fully automatic way. Time efficiency and user friendliness of the signal analysis can thus be increased. In an embodiment, the machine learning model is implemented as a machine learning algorithm.

In an embodiment, a threshold may be used for classifying the signal segments as either the normal segments or as the outlier segments. Accordingly, how the classification operates can be influenced by adapting the threshold. For example, the ratio of identified normal segments to identified outlier segments for a given measurement signal depends on the threshold.

In an embodiment, the threshold is adaptable via a user interface of a test and/or measurement instrument. Hence, a user is enabled to adjust the classification of the signal segments by adapting the threshold. The adjustment is particularly user-friendly since it only depends on one single parameter (the threshold).

In an embodiment, an anomaly score may be determined for the signal segments. A user can thus be provided with information regarding individual signal segments for a more detailed evaluation of the measurement signal.

In another embodiment, a confidence interval for the anomaly score may be determined. The user can thus be provided with information about the reliability of the determined anomaly scores.

According to one aspect, the measurement signal, for example, may be a frequency-transformed signal. Signal analysis and particularly outlier detection can thus be enabled for the frequency domain. In particular, the frequency-transformed signal is a discrete Fourier transform of an original signal.

According to another aspect, the measurement signal, for example, may be a track signal. In an embodiment, a track signal is a waveform generated by applying a mathematical function to an original signal. Detecting anomalies in the track signal may be easier than in the original signal. Accordingly, using a track signal can improve a precision of the anomaly detection.

For applying the model in an embodiment, at least one of a statistical algorithm or a machine learning model may be run. Hence, anomalies can be detected in the measurement signal without relying on prior knowledge about characteristics of potential anomalies. In an embodiment, a degree of similarity between signal segments of the measurement signal may be quantified by the statistical algorithm and/or the machine learning model. In an embodiment, the degree of similarity is quantified by a similarity measure determined for the signal segments by the statistical algorithm and/or the machine learning model.

Moreover, a plurality of measurement signals may be, for example, received simultaneously, wherein the model is applied to the plurality of measurement signals. A plurality of measurement signals can thus be analyzed in parallel, for example regarding an occurrence of anomalies.

In an embodiment, a correlation between at least two of the measurement signals may be determined when applying the model to the plurality of measurement signals. Hence, additional information is provided for the signal analysis, for example for detecting anomalies in the measurement signals. For example, a reduced correlation between measurement signals may be taken into account as an indication that an anomaly is present in at least one of the considered measurement signals.

The present disclosure further provides a method of evaluating a condition for a trigger of an oscilloscope. In an embodiment, the method comprises analyzing a measurement signal according to the analysis method described herein. The method further comprises evaluating a condition for the trigger of the oscilloscope based on a result of the analysis.

Accordingly, a trigger can be provided that is based on a signal analysis that does not require a complex preliminary setup of analysis parameters. For example, the condition for the trigger may be a detection of an anomaly. Hence, a trigger can be provided that is based on an anomaly detection which does not rely on prior knowledge about characteristics of potential anomalies.

According to one aspect, a plurality of conditions, for example, may be evaluated. In an embodiment, it is evaluated in which temporal order the conditions are fulfilled, such that a sequence triggering is enabled.

In an embodiment, at least one of the conditions may be a detection of an anomaly. As one example, three conditions may be evaluated sequentially, wherein the condition to be evaluated last (i.e. third) is an anomaly detection.

In addition, the present disclosure provides a test and/or measurement instrument with an electronic circuit configured for performing a method of analyzing a measurement signal in real time. In an embodiment, the electronic circuit is configured to execute the steps of: receiving a measurement signal, wherein the measurement signal is a digitized signal; and applying a model to the measurement signal, thereby creating an embedding of signal segments of the measurement signal in a manifold where signal segments having a higher degree of similarity between each other are positioned closer to one another in the manifold and signal segments having a lower degree of similarity between each other are positioned more distant to one another in the manifold.

Hence, real-time signal analysis and in particular real-time outlier detection can be enabled. Moreover, the measurement signal can be analyzed without having to perform a complex preliminary setup of analysis parameters. Instead, a mostly or fully automatic signal analysis can be provided by applying the model to the measurement signal.

In an embodiment, the test and/or measurement instrument may further be configured for triggering an action based on a result of the measurement signal analysis. Thus, a trigger can be provided that is based on real-time signal analysis and for example on real-time outlier detection.

In an embodiment, the test and/or measurement instrument may further comprise a plurality of input ports. The test and/or measurement instrument may be configured to receive a plurality of measurement signals simultaneously via the input ports. In an embodiment, the electronic circuit may be configured to apply the model to the plurality of measurement signals and to determine a correlation between at least two of the measurement signals for identifying outlier segments within the plurality of measurement signals.

Accordingly, the electronic circuit takes into account additional information for the signal analysis, for example for detecting anomalies in the measurement signals. A detection accuracy can thus be increased. For example, a reduced correlation between measurement signals may be considered by the electronic circuit as an indication that an anomaly is present in at least one of the measurement signals.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 is a schematic overview diagram illustrating an embodiment of a method of analyzing a measurement signal according to an aspect of the present disclosure;

FIG. 2 is a flow chart schematically illustrating an embodiment of a method of analyzing a measurement signal according to an aspect of the present disclosure;

FIG. 3 is a flow chart schematically illustrating an embodiment of a method of evaluating a condition for a trigger of an oscilloscope according to another aspect of the present disclosure; and

FIG. 4 is a diagram schematically illustrating a test and/or measurement instrument according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

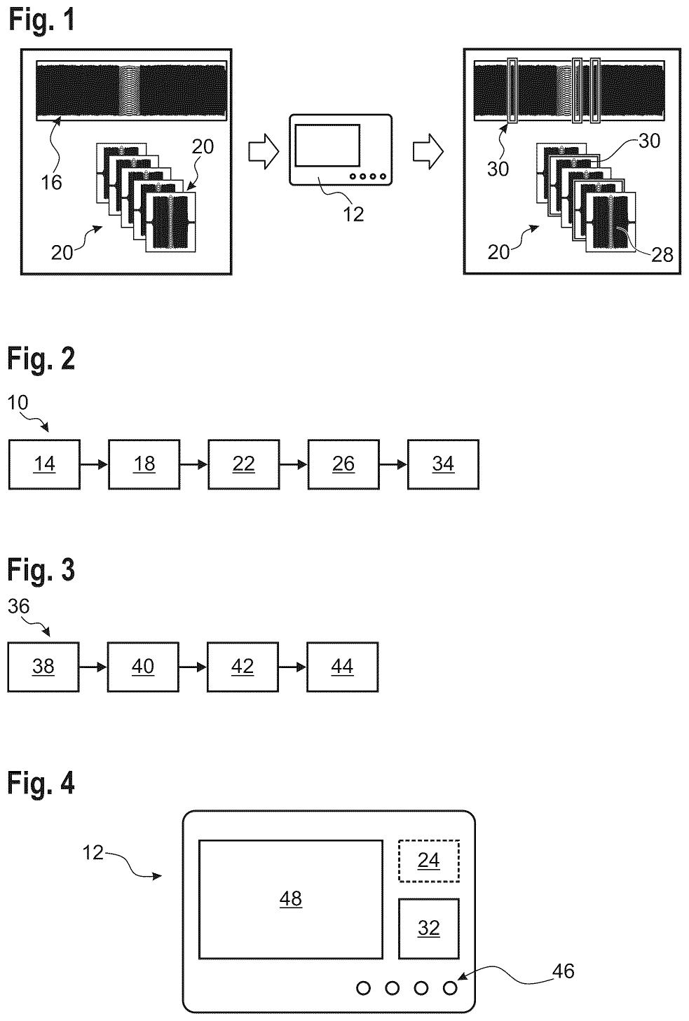

FIG. 1 is a schematic overview diagram illustrating an example embodiment of a method of analyzing a measurement signal according to an aspect of the present disclosure. In an embodiment, the method may be performed by a test and/or measurement instrument 12. A flow chart schematically illustrating an example embodiment of the method is depicted in FIG. 2.

As shown in FIG. 2, the method 10 comprises, in a step 14, receiving a measurement signal 16. The measurement signal 16 is a digitized signal and may relate to a measured voltage. For example, the measured signal may be a radar pulse, a non-return-to-zero signal, or a pulse-amplitude modulation signal. According to one aspect, the measurement signal 16 may be a frequency-transformed signal or a track signal.

As shown in FIG. 2, the method 10 may also comprise, in a step 18, segmenting the received measurement signal 16. Accordingly, signal segments 20 (see FIG. 1) can be obtained from the measurement signal 16. In an embodiment, an original waveform of the measurement signal 16 is split into consecutive shorter waveforms, i.e. the signal segments 20.

Still referring to FIG. 2, the method 10 further comprises, in a step 22, applying a model to the measurement signal 16. Thereby, an embedding of signal segments 20 of the measurement signal 16 in a manifold is created. In an embodiment, the embedding of the segments in the manifold is a latent space.

Signal segments 20 having a higher degree of similarity between each other are positioned closer to one another in the manifold. Signal segments 20 having a lower degree of similarity between each other are positioned more distant to one another in the manifold. In an embodiment, a degree of similarity between different signal segments 20 of the measurement signal 16 is quantified by determining a similarity measure for different signal segments 20 of the measurement signal 16, respectively.

In an embodiment, the model may be applied to the measurement signal 16 by an electronic circuit 24 in real time, for example an electronic circuit 24 of a test and/or measurement instrument 12 as described further below with regard to FIG. 4. Real-time signal analysis and in particular real-time outlier detection can thus be enabled. For applying the model, at least one of a statistical algorithm or a machine learning model may be run.

The method 10 may also comprise, in a step 26 (see FIG. 2), classifying the signal segments 20 as either normal segments 28 or as outlier segments 30, according to their position within the manifold. In an embodiment, the normal segments 28 and the outlier segments 30 are spaced from each other within the manifold. In addition, an average distance between a normal segment 28 and an outlier segment 30 within the manifold may be larger than an average distance between two normal segments 28 and/or an average distance between two outlier segments 30.

In an embodiment, a metric may be used to determine the frequency or the count of the normal segments 28 and the outlier segments 30. In an embodiment, the metric is a metric tensor. For example, the metric may be determined via a machine learning model. Hence, the metric can be determined in a mostly or fully automatic way.

Further, a threshold may be used for classifying the signal segments 20 as either the normal segments 28 or as the outlier segments 30. In an embodiment, the threshold is adaptable via a user interface 32 of a test and/or measurement instrument 12. Accordingly, the user can influence how the classification operates by adapting the threshold.

In an embodiment, the anomaly score may be determined for the signal segments 20. A user can thus be provided with information regarding individual signal segments 20 for a more detailed evaluation of the measurement signal 16. In addition, a confidence interval for the anomaly score may be determined.

According to another aspect, a plurality of measurement signals 16, for example, may be received simultaneously, wherein the model is applied to the plurality of measurement signals 16. A correlation between at least two of the measurement signals 16 may be determined when applying the model to the plurality of measurement signals 16.

In an embodiment, the method 10 (see FIG. 2) further comprises, in a step 34, outputting a frequency or a count of normal segments 28 and outlier segments 30 as data. Additionally or alternatively, the frequency or the count of normal segments 28 and outlier segments 30 may be visualized in a generated diagram.

Moreover, a user feedback regarding the detection of normal segments 28 and outlier segments 30 may be used for improving the model, e.g. the machine learning model or the statistical algorithm. The user may for example be provided with an option of indicating agreement or disagreement with results of the model regarding individual signal segments 20.

FIG. 3 is a flow chart schematically illustrating an example embodiment of method 36 of evaluating a condition for a trigger of an oscilloscope according to another aspect of the present disclosure.

The method 36 comprises, in a step 38, analyzing a measurement signal 16 according to the analysis method described herein, for example as described above with regard to FIGS. 1 and 2. The method 36 also comprises evaluating a condition for the trigger of the oscilloscope based on a result of the analysis. A plurality of conditions may be evaluated. In an embodiment, it is evaluated in which temporal order the conditions are fulfilled, such that a sequence triggering is enabled. In this regard, the method 36 shown in FIG. 3 comprises evaluating a first condition in a step 40, evaluating a second condition in a step 42, and evaluating a third condition in a step 44.

At least one of the conditions may be a detection of an anomaly. In the example depicted in FIG. 3, the third condition, in step 44, is an anomaly detection. The first condition, in step 40, is an edge trigger and the second condition, in step 42, is a zone trigger. In an embodiment, the zone trigger is for preselecting interesting (e.g. potentially anomalous) signal segments 20.

FIG. 4 is a diagram schematically illustrating a test and/or measurement instrument 12 according to an embodiment of the present disclosure. In an embodiment, the test and/or measurement instrument 12 is an oscilloscope.

As shown in FIG. 4, the test and/or measurement instrument 12 comprises an electronic circuit 24 configured for performing a method 10 of analyzing a measurement signal 16 in real time. The electronic circuit 24 is configured to execute the steps of the analysis m FIGS. 1 and 2. The test and/or measurement instrument 12 may further be configured for triggering an action based on a result of the measurement signal analysis.

In an embodiment, for example as shown in FIG. 4, the test and/or measurement instrument 12 may further comprise a plurality of input ports 46. The test and/or measurement instrument 12 may be configured to receive a plurality of measurement signals 16 simultaneously via the input ports 46.

In an embodiment, the electronic circuit 24 may be configured to apply the model to the plurality of measurement signals 16 and to determine a correlation between at least two of the measurement signals 16 for identifying outlier segments 30 within the plurality of measurement signals 16. In an embodiment, timing anomalies between the measurements signals can be identified. For example a sequence and a timing of power supply voltages can thus be monitored.

As also shown in FIG. 4, the test and/or measurement instrument 12 may further comprise a display 48, where results of the signal analysis performed by the electronic circuit 24 can be output. For example, a diagram visualizing a frequency or a count of normal segments 28 and outlier segments 30 can be displayed.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field programmable gate array (FPGA), a system on a chip (SoC), a graphics processing unit (GPU) or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the instrument 12, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible to a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method of analyzing a measurement signal, comprising:
receiving a measurement signal, wherein the measurement signal is a digitized signal; and
applying a model to the measurement signal, thereby creating an embedding of signal segments of the measurement signal in a manifold where signal segments having a higher degree of similarity between each other are positioned closer to one another in the manifold and signal segments having a lower degree of similarity between each other are positioned more distant to one another in the manifold.

2. The method according to claim 1, wherein the signal segments are classified as either normal segments or as outlier segments, according to their position within the manifold.

3. The method according to claim 2, wherein the normal segments and the outlier segments are spaced from each other within the manifold.

4. The method according to claim 2, wherein a frequency or a count of normal segments and outlier segments is at least one of output as data or visualized in a diagram generated.

5. The method according to claim 1, wherein the model is applied to the measurement signal by an electronic circuit in real time.

6. The method according to claim 2, wherein a metric is used to determine a frequency or a count of the normal segments and the outlier segments.

7. The method according to claim 6, wherein the metric determined via a machine learning model.

8. The method according to claim 2, wherein a threshold is used for classifying the signal segments as either the normal segments or as the outlier segments.

9. The method according to claim 8, wherein the threshold is adaptable via a user interface of a test and/or measurement instrument.

10. The method according to claim 1, wherein an anomaly score is determined for the signal segments.

11. The method according to claim 10, wherein a confidence interval for the anomaly score is determined.

12. The method according to claim 1, wherein the measurement signal is at least one of a frequency-transformed signal or a track signal.

13. The method according to claim 1, wherein for applying the model, at least one of a statistical algorithm or a machine learning model is run.

14. The method according to claim 1, wherein a plurality of measurement signals is received simultaneously and wherein the model is applied to the plurality of measurement signals.

15. The method according to claim 14, wherein a correlation between at least two of the measurement signals is determined when applying the model to the plurality of measurement signals.

16. A method of evaluating a condition for a trigger of an oscilloscope, wherein the method comprises analyzing a measurement signal according to the method of claim 1, and evaluating a condition for the trigger of the oscilloscope based on a result of the analysis.

17. The method according to claim 16, wherein a plurality of conditions is evaluated and wherein it is evaluated in which temporal order the conditions are fulfilled, such that a sequence triggering is enabled.

18. A test and/or measurement instrument, comprising:
electronic circuitry configured for performing a method of analyzing a measurement signal in real time, wherein the electronic circuitry is configured to:
receive a measurement signal, wherein the measurement signal is a digitized signal; and
apply a model to the measurement signal, thereby creating an embedding of signal segments of the measurement signal in a manifold where signal segments having a higher degree of similarity between each other are positioned closer to one another in the manifold and signal segments having a lower degree of similarity between each other are positioned more distant to one another in the manifold.

19. The test and/or measurement instrument according to claim 18, wherein the electronic circuitry is further configured for triggering an action based on a result of the measurement signal analysis.

20. The test and/or measurement instrument according to claim 18, further comprising a plurality of input ports configured to simultaneously receive a plurality of measurement signals, wherein the electronic circuitry is configured to apply the model to the plurality of measurement signals and to determine a correlation between at least two of the measurement signals for identifying outlier segments within the plurality of measurement signals.
